(19) United States
(12) Patent Application Publication
(10) Pub. No.: US 2014/0130848 A1
(43) Pub. Date: May 15, 2014

(54) SOLAR CELL MODULE

(71) Applicant: Panasonic Corporation, Osaka (JP)

(72) Inventors: YOHEI TAKECHI, Osaka (JP); KENICHIRO MASE, Osaka (JP)

(73) Assignee: Panasonic Corporation, Osaka (JP)

(21) Appl. No.: 14/054,828

(22) Filed: Oct. 16, 2013

(30) Foreign Application Priority Data
Nov. 12, 2012 (JP) 2012-248132

(51) Int. Cl. H01L 31/048; H01L 31/045

(52) U.S. Cl. CPC H01L 31/048; H01L 31/045
USPC 136/251

(57) ABSTRACT

A flexible solar cell sheet includes plural through incisions provided between solar cell strings in a direction along the solar cell strings. The solar cell sheet is bonded to a transparent curved surface substrate having three-dimensional curvature. Stress generated inside a surface of the solar cell sheet when the sheet is bonded along the curved surface of the transparent curved surface substrate can be alleviated by the through incisions, and bonding can be performed while suppressing twists and wrinkles occurring in the solar cell sheet.

### CROSS REFERENCE TO RELATED APPLICATIONS

This application claims the benefit of foreign priority to Japanese Patent Application No. 2012-248132, filed on Nov. 12, 2012, the contents of which are incorporated herein by reference.

### BACKGROUND

1. Technical Field

The technical field relates to a solar cell module.

2. Background Art

A related-art solar cell module is generally constructed by filling transparent resin (EVA) between a flat glass plate and a weather resistance film and sandwiching solar cells therebetween. In order to give flexibility to the solar cell module, there is proposed a solar cell module constructed by sealing solar cells by using a transparent film member instead of the glass plate to thereby allow the solar cell module to bend with flexibility (refer to JP-A-9-51118 (Patent Document 1) and JP-A-2006-165169 (Patent Document 2)).

In recent years, not only horizontal installation of flat-plate modules such as installation on house roofs and a large-scale photovoltaic power plant but also applications of constructing and installing the solar cell modules on curved portions of buildings, spherical and dome shaped portions such as roofs, hoods and doors of cars are increasing.

### SUMMARY

However, when the solar cell module is constructed on portions having a three-dimensional curvature such as a shape obtained by abstracting part of a sphere surface or an oval-sphere surface, or the dome shape as in above-described roofs of cars, window glass and so on, the above related-art solar cell module formed by the flat glass plate has extremely low flexibility, therefore, it is difficult to bond or fix the solar cell module along curvature portions.

In the related-art structure of using the transparent film member, bending along a side surface of a cylindrical shape, namely, bending in one direction is relatively easy, however, in a shape requiring bending in two or more directions at the same time, wrinkles and forced tension occur in the film member forming the module, therefore, thus, it is extremely difficult to bond or fix the solar cell module along the curved surface.

Furthermore, it is possible to consider a method of directly bonding solar cells one by one to a substrate made of resin or a glass material having a spherical curved surface to thereby construct the solar cell module, not forming the solar cell module in advance, however, productivity is low in this method as most of manufacturing processes are performed by hand, and the method is not adequate to commercial production.

In view of the above problems of the related art, as well as other concerns, a concern of the present disclosure is a solar cell module with high productivity and reliability while having a spherical curved surface as the entire shape.

A solar cell module according to one or more embodiments includes a laminate solar cell sheet in which plural solar cells electrically wire-connected are sealed by transparent members and plural incision portions piercing through the film members are provided among an array of the solar cells, and a curved surface substrate having a desired curved-surface shape, and the solar cell module is formed by a process of bonding the laminate solar cell sheet to the curved surface substrate so as to fit to the curved surface of the substrate.

Accordingly, a solar cell module with high reliability as a solar cell module, high productivity as an industrial product as well as having a spherical curved surface which is highly customized such as such roofs or exteriors of cars, outer walls of buildings, etc. can be realized.

### BRIEF DESCRIPTION OF THE DRAWINGS

FIG. 1 is a view showing a structure of a solar cell sheet according to Embodiments 1 and 2;

FIG. 2 is a view showing a shape of a transparent curved surface substrate according to Embodiments 1 and 2;

FIG. 3 is a view showing a solar cell module according to Embodiment 1;

FIG. 4A is a view showing a cross section of the solar cell module in a direction from the near side to the back side of FIG. 3, and FIG. 4B is a view showing a cross section of the solar cell module in a right and left direction of FIG. 3;

FIG. 5 is a view showing a solar cell module according to Embodiment 2;

FIG. 6A is a view showing a cross section of the solar cell module in a direction from the near side to the back side of FIG. 5, and FIG. 6B is a view showing a cross section of the solar cell module in a right and left direction of FIG. 5 in Embodiment 2;

FIG. 7 is a view showing a first example of an extracting method of extraction electrodes in Embodiment 2;

FIG. 8 is a view showing a second example of an extracting method of extraction electrodes in Embodiment 2; and

FIG. 9 is a view showing a related-art solar cell module described in Patent Document 1.

### DESCRIPTION OF THE PREFERRED EMBODIMENTS

Hereinafter, exemplary embodiments will be explained with reference to the drawings.

### Embodiment 1

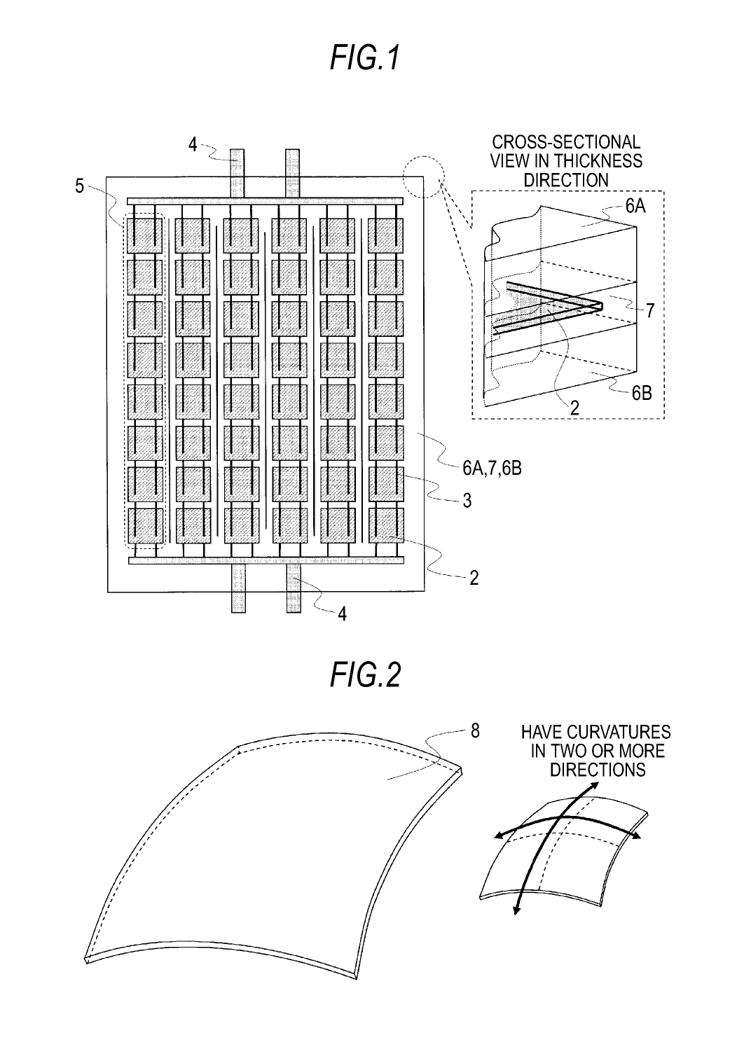

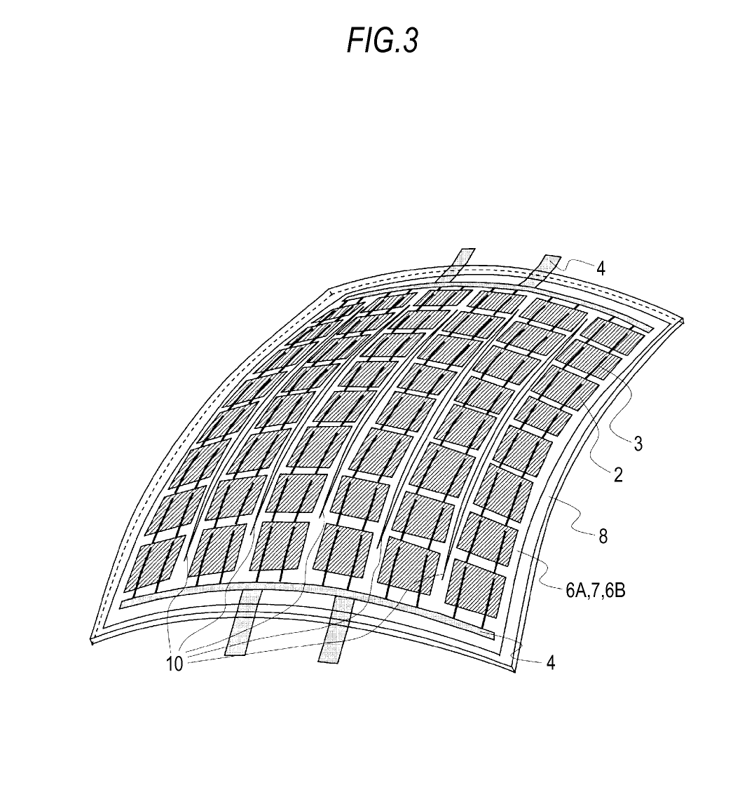

FIG. 1 is a view showing a solar cell sheet 1 included in a solar cell module shown in FIG. 3.

The solar cell sheet 1 according to the present embodiment includes at least plural solar cells 2, tabs between cells 3 electrically connecting adjacent solar cells 2 and a pair of transparent sheets (a front-face transparent sheet 6A and a rear-face sheet 6B sandwiching the cells 2 from both sides).

The solar cell sheet 1 usually requires, in addition to the above components, extraction electrodes 4 for electrically connecting both ends of solar cell strings 5 including plural solar cells 2 and extracting electric current to the outside of the solar cell sheet 1 and a filler resin 7 for filling in among the solar cells 2, the tabs between cells 3 and the extraction electrodes 4.

In the solar cell sheet 1, through incisions 10 piercing through the front-face transparent sheet 6A, the rear-face sheet 6B and the filler resin 7 are formed between strings of the solar cell strings 5 sealed with the front-face transparent sheet 6A, the rear-face sheet 6B and the filler resin 7 so as to pierce in a direction from the near side to the back side of FIG. 3. The plural through incisions 10 are formed in one direction and are provided along at least two or more solar cells 2 as shown in FIG. 3. The through incisions 10 are preferably provided so that the length thereof is gradually increased from the center toward both ends as shown in FIG. 3.

The front-face transparent sheet 6A and the rear-face sheet 6B are made of, for example, resin such as PET with flexibility. At least the front-face transparent sheet 6A is transparent, and in the case where the solar cells 2 to be used are solar cells supporting double-sided generation, it is preferable that the rear-face sheet 6B is also transparent. The tabs between cells 3 are metal wiring lines or made of a material having conductivity as well as flexibility such as conductive resin. Moreover, the filler resin 7 is a transparent material having rubber-like flexibility even after a sealing processing such as EVA (ethylene-vinyl acetate).

FIG. 2 shows a transparent curved surface substrate 8 included in the solar cell module of FIG. 3 according to Embodiment 1.

The transparent curved surface substrate 8 has a curved surface having a three-dimensional curvature as in a shape obtained by cutting out part of a spherical surface or an oval-sphere surface. Materials for the transparent curved surface substrate 8 maybe resin such as polycarbonate and glass as long as it is transparent.

FIG. 3 is the entire view of the solar cell module according to Embodiment 1.

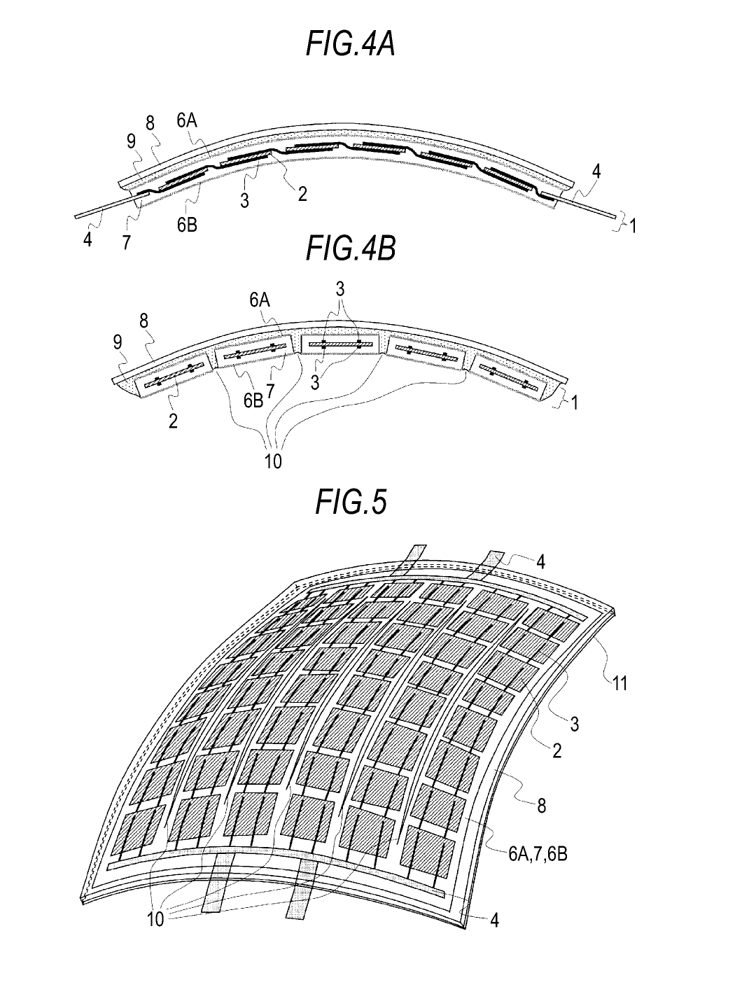

FIG. 4A is a cross-sectional view showing from the extraction electrode 4 in the back side to the extraction electrode 4 in the near side in FIG. 3. A portion between the transparent curved surface substrate 8 and the solar cell sheet 1 under the substrate is filled with a fixing filler resin 9 to thereby bond the transparent curved surface substrate 8 and the solar cell sheet 1 to each other.

Here, the fixing filler resin 9 is assumed to be transparent.

FIG. 4B is a cross-sectional view showing from the left side to the right side of a central portion of the solar cell module of FIG. 3.

In FIG. 1 and FIG. 3, a vertical relationship and a stacking manner of members included in the solar cell sheet 1 and the solar cell module are complicated, and the transparent curved surface substrate 8, the fixing filler resin 9 and the front-face transparent sheet 6A are actually transparent and members arranged on the back side of these members can be seen through them, therefore, even when a certain member in the drawings is shown as positioned on the back side of another member, the outline shape thereof is not represented by a dashed line.

The vertical relationship and the staking manner of members included in the solar cell sheet 1 and the solar cell module in Embodiment 1 are shown in detail in FIG. 4A and FIG. 4B.

Next, purposes of forming the through incisions 10 in the solar cell sheet 1 will be explained.

When the solar cell sheet 1 is bonded and fixed to the transparent curved surface substrate 8 by the fixing filler resin 9, tensile stress occurs in the surface of the solar cell sheet 1 as the solar cell sheet 1 originally formed/sealed in the flat surface is bonded along the transparent curved surface substrate 8 having the three-dimensional curvature. As a result, the solar cell sheet 1 may be disfigured such that twists or wrinkles occur on the periphery of the sheet, or peeling from the transparent curved surface substrate 8 tends to occur from the generated twists or wrinkles on the solar cell sheet 1. As a result, disadvantages may arise also in functional aspects as the solar cell module.

In the present embodiment, the through incisions 10 provided between strings of the solar cell strings 5 of the solar cell sheet 1 slightly open, thereby alleviating the tensile stress in the surface occurring when the solar cell sheet 1 is bonded along the curved surface, which allows the solar cell sheet 1 to be bonded along the transparent curved surface substrate 8 without occurrence of twists or wrinkles on the sheet.

Additionally, the length of the through incisions 10 along the solar cell strings 5 is gradually increased as coming toward both ends as compared with the length of the through incision at the center of the solar cell sheet 1, thereby suppressing occurrence of twists or wrinkles of the sheet near the extraction electrodes 4.

In the direction from the extraction electrode 4 in the back side to the extraction electrode 4 in the near side in FIG. 3, bending occurring by bonding the sheet along the transparent curved surface substrate 8 is absorbed at portions between the solar cells 2 included in the solar cell strings 5 as shown in FIG. 4A. In a direction from the left side to the right side in the central portion of the solar cell module of FIG. 3, bending occurring by bonding the sheet along the transparent curved surface substrate 8 is absorbed by separating adjacent solar cell strings 5 from one another by the through incisions 10 as shown in FIG. 4B.

Moreover, a provisional solar cell module is once constructed in the state of the solar cell sheet 1 to be bonded to the transparent curved surface substrate 8, not bonding the solar cells 2 directly to the curved surface of the transparent curved surface substrate 8. According to the construction method, the solar cell sheet 1 can be fabricated by a well-known solar cell lamination technique, and reliability of the solar cell module can be assured in the same level as in the related art. Additionally, as the solar cell sheet 1 in which the solar cells 2 are arranged at predetermined positions is bonded to the transparent curved surface substrate 8, it is possible to easily fabricate the solar cell module with high quality in appearance as well as having the three-dimensional curved surface without requiring man-hours.

It is not always necessary to completely fill between the solar cell sheet 1 and the transparent curved surface substrate 8 with the fixing filler resin 9 as in the present Embodiment 1 as long as the solar cell sheet 1 can be fixed so as to be arranged along the transparent curved surface substrate 8 as well as light passing through the transparent curved surface substrate 8 from an upper surface side of the transparent curved surface substrate 8 and reaching a light-receiving generation surface of the solar cells 2 sealed in the solar cell sheet 1 is not completely blocked.

It is also preferable that a part between the solar cell sheet 1 and the transparent curved surface substrate 8 is filled. Furthermore, the solar cell sheet 1 and the transparent curved surface substrate 8 can be bonded and fixed to each other by double-faced tape and the like instead of using the fixing filler resin 9.

### Embodiment 2

FIG. 5 is the entire view of a solar cell module according to Embodiment 2.

In Embodiment 2, as the solar cell sheet 1 and the transparent curved surface substrate 8 included in the solar cell module are the same as ones explained in Embodiment 1, therefore, the same reference numerals are used for them and the explanation will be omitted.

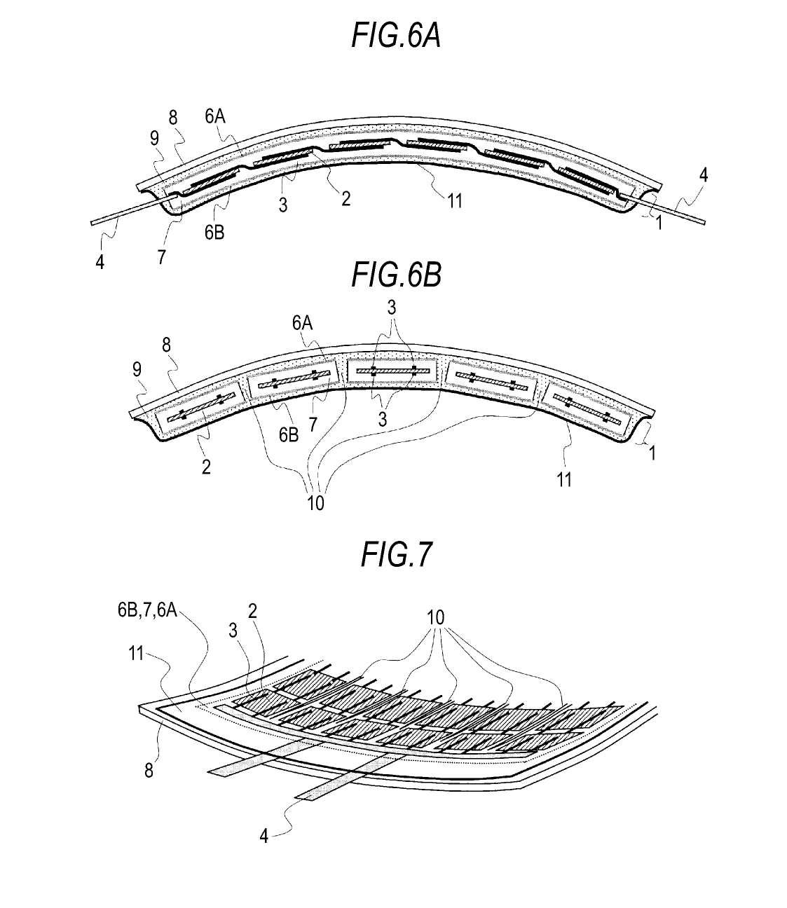

FIG. 6A is a cross-sectional view showing from the extraction electrode 4 in the back side to the extraction electrode 4 in near side in FIG. 5. A different point between the above Embodiment 1 and the present embodiment is as follows. The solar cell sheet 1 and the transparent curved surface substrate 8 are bonded and fixed with just the fixing filler resin 9 in FIG. 4A in Embodiment 1, whereas in Embodiment 2, the solar cell sheet 1 is sandwiched between the transparent curved surface substrate 8 and a rear-face sealing sheet 11, and its surrounded closed space is filled with the fixing filler resin 9 to thereby seal the solar cell sheet 1 in the bonded and fixed state as shown in FIG. 6A.

FIG. 6B is a cross-sectional view from the left side to the right side in a central portion of the solar cell module of FIG. 5.

Here, the rear-face sealing sheet 11 is made of, for example, resin such as PET with flexibility in the same manner as the rear-face sheet 6B, and when the solar cells 2 to be used are solar cells supporting double-sided generation, it is preferable that the rear-face sealing sheet 11 is also transparent. The extraction electrodes 4 may be led out from an end portion of the rear-face sealing sheet 11 as well as from incisions 12 provided on the rear-face sealing sheet 11.

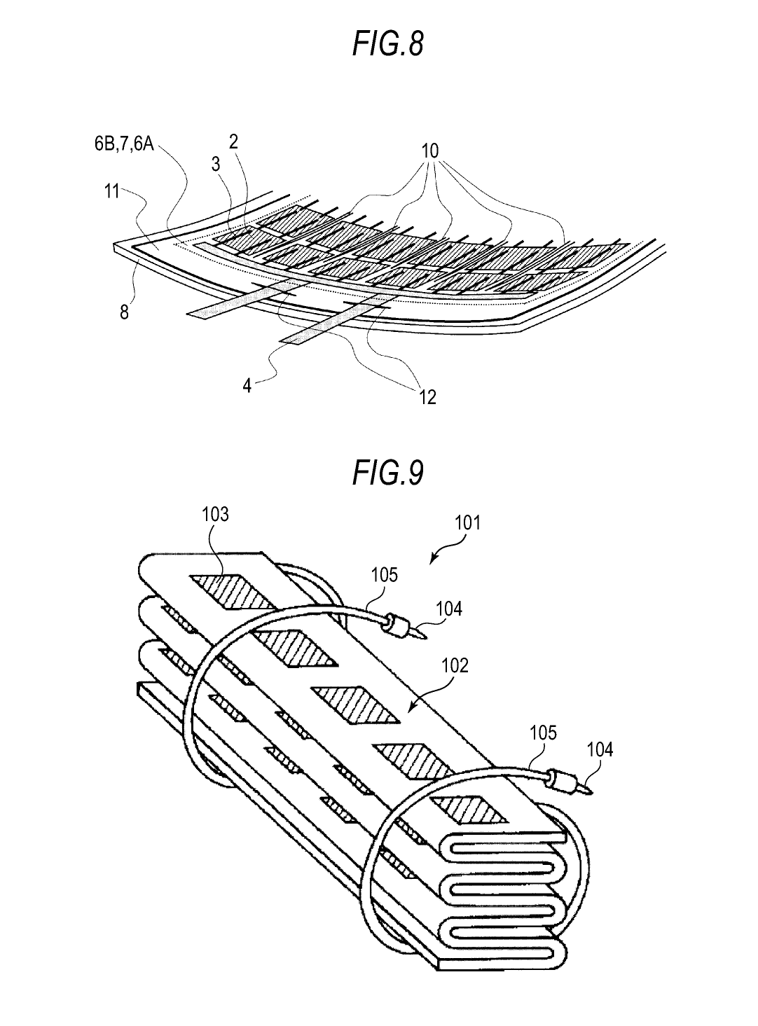

In FIG. 5, FIG. 7 and FIG. 8, even when a certain member in the drawings is positioned on the back side of another member, the outline shape thereof is not represented by a dashed line due to the same reason already explained in Embodiment 1. The vertical relationship and the stacking manner of members included in the solar cell sheet 1 and the solar cell module in Embodiment 2 are shown in detail in FIG. 6A and FIG. 6B.

In the direction from the extraction electrode 4 in the back side to the extraction electrode 4 in the near side in FIG. 5, bending occurring by bonding the sheet along the transparent curved surface substrate 8 is absorbed at portions between the solar cells 2 included in the solar cell strings 5 as shown in FIG. 6A. In a direction from the left side to the right side in the central portion of the solar cell module of FIG. 5, bending occurring by bonding the sheet along the transparent curved surface substrate 8 is absorbed by separating adjacent solar cell strings 5 from one another by the through incisions 10 as shown in FIG. 6B.

As the solar cell sheet 1 is sandwiched by the transparent curved surface substrate 8 and the rear-face sealing sheet 11, and the space between them is filled with the fixing filler resin 9 to be fixed therebetween, the entire solar cell module can be sealed without dropping or overflow of the fixing filler resin to the opposite side of the transparent curved surface substrate 8 through the through incisions 10. Accordingly, the solar cell module can be easily fabricated with the rear side of the module in good appearance. The effect is useful for an application in which not only the front face of the solar cell module but the rear face of the module is directly seen by users in the final product such as the case where the solar cells 2 are solar cells supporting the double-sided generation.

The same structure as explained in Embodiment 1 is applied, in which the provisional module is once constructed in the state of the solar cell sheet 1 to be bonded to the transparent curved surface substrate 8, therefore, reliability of the solar cell module can be assured in the same level as in the related art and it is possible to fabricate the solar cell module with high quality in appearance as a product as well as having the three-dimensional curved surface easily without requiring man-hours in the same manner as explained in Embodiment 1.

The solar cell module according to the various embodiments can be applied to members having the spherical shape which is highly customized such as roofs and exteriors of cars and outer walls of buildings, and can be particularly applied to installation of the solar cell module in members having curved surfaces in outer walls or window glass of public facilities such as museums and installation on roofs, hoods, trunks and doors of cars, outer wall portions of airplanes, ships and railroad vehicles.

What is claimed is:

1. A solar cell module comprising:
a solar cell sheet including
a plurality of solar cells,
tabs electrically connecting the plurality of solar, cells and
a transparent sheet; and
a substrate with a curved-surface shape,
wherein a plurality of through incisions provided between the plurality of solar cells and piercing through the solar cell sheet in one direction are formed at least along two or more solar cells in the solar cell sheet.

2. The solar cell module according to claim 1,
wherein the through incisions are formed at portions not damaging the solar cells,
the solar cell module further comprising extraction electrodes which together with the tabs extract electric power from the plurality of solar cells in the solar cell sheet.

3. The solar cell module according to claim 1,
wherein the substrate and the filler resin for bonding the substrate to the solar cells are transparent.

4. The solar cell module according to claim 1,
wherein the plurality of solar cells are arranged in a plurality of solar cell strings in a first direction,
wherein each of the plurality of through incisions is provided between adjacent solar cell strings,
wherein a length of each of the plurality of through incisions in the first direction increases from a through incision at a center of the solar cell sheet to the through incisions at the ends of the solar cell sheet in a second direction perpendicular to the first direction.

5. The solar cell module according to claim 3,
wherein, at the time of bonding the solar cell sheet to the substrate, the solar cell sheet is sandwiched between a rear-face sealing sheet and the substrate so that space between the rear-face sealing sheet and the substrate is filled with the filler resin.

6. The solar cell module according to claim 4,
wherein, at the time of bonding the solar cell sheet to the substrate, the solar cell sheet is sandwiched between a rear-face sealing sheet and the substrate so that space between the rear-face sealing sheet and the substrate is filled with the filler resin.

7. The solar cell module according to claim 2,
wherein the substrate and the filler resin for bonding the substrate to the solar cells are transparent.

8. The solar cell module according to claim 3,
wherein the size relation in lengths L1, Ln, Ln′ (n natural number of n≧2) of the plurality of through incisions provided from the center of the solar cell sheet to neighboring right and left portions is
L1≦L2≦L3≦ . . . ≦Ln≦Ln+1≦ . . . ,
L1≦L2′≦L3′≦ . . . ≦Ln′≦Ln+1′≦ . . . ,
wherein:
a length of the through incision provided a portion between solar cell strings 1 at the center of the solar cell sheet is L1,
lengths of the through incisions provided in a portion between solar cell strings 2 and a portion between solar cell strings 2′ which are right and left adjacent to the portion between solar cell strings 1 are respectively L2 and L2′, and
lengths of the through incisions provided in a portion between solar cell strings 3 and a portion between solar cell strings 3′ which are adjacent to the portions between solar cell strings 2 and 2′ in reverse direction to the portion between solar cell strings 1 are respectively L3, L3′.
